(19) United States
(12) Patent Application Publication
(10) Pub. No.: US 2026/0068111 A1
(43) Pub. Date: Mar. 5, 2026

(54) Cooling Profiles in Wireless Charging Systems

(71) Applicant: Apple Inc., Cupertino, CA (US)

(72) Inventors: Ashley Van Der Merwe, Pokeno (NZ); Arunim Kumar, San Jose, CA (US); Zaid A AbuKhalaf, Sunnyvale, CA (US)

(21) Appl. No.: 19/264,225

(22) Filed: Jul. 9, 2025

Related U.S. Application Data
(60) Provisional application No. 63/688,422, filed on Aug. 29, 2024.
(60) Provisional application No. 63/711,068, filed on Oct. 23, 2024.

(51) Int. Cl. H05K 7/20; H02J 50/10; H02J 50/80

(52) U.S. Cl. CPC H05K 7/20945; H02J 50/10; H02J 50/80

(57) ABSTRACT

A wireless charging system may include a wireless power receiving device that receives wireless power signals from a wireless power transmitting device. The wireless power transmitting device may transmit cooling capabilities information to the wireless power receiving device. The wireless power receiving device may transmit a cooling profile request to the wireless power transmitting device.

This application claims the benefit of U.S. provisional patent application No. 63/711,068, filed Oct. 23, 2024, and U.S. provisional patent application No. 63/688,422, filed Aug. 29, 2024, which are hereby incorporated by reference herein in their entireties.

### FIELD

This relates generally to power systems, including wireless power systems for charging electronic devices.

### BACKGROUND

In a wireless charging system, a wireless power transmitting device transmits wireless power to a wireless power receiving device. The wireless power receiving device charges a battery and/or powers components using the wireless power. Under some usage conditions, temperature of a wireless power transmitting device and/or a wireless power receiving device may increase during wireless charging operations.

### SUMMARY

An electronic device may include a wireless power transfer coil, a rectifier operably coupled to the wireless power transfer coil, and control circuitry operably coupled to the wireless power transfer coil and rectifier and configured to: receive a first packet that identifies cooling level information and noise level information for a plurality of cooling profiles from an additional electronic device using the wireless power transfer coil and transmit a second packet to the additional electronic device using the wireless power transfer coil. The second packet may identify a requested cooling profile of the plurality of cooling profiles.

An electronic device may include a wireless power transfer coil, an inverter that is configured to supply alternating-current drive signals to the wireless power transfer coil, one or more cooling systems, and control circuitry operably coupled to the wireless power transfer coil, the inverter, and the one or more cooling systems and configured to: transmit a first packet that identifies cooling level information and noise level information for a plurality of cooling profiles to an additional electronic device using the wireless power transfer coil, receive a second packet that identifies a requested cooling profile of the plurality of cooling profiles from the additional electronic device using the wireless power transfer coil, and operate the one or more cooling systems according to the requested cooling profile.

### BRIEF DESCRIPTION OF THE DRAWINGS

FIG. 1 is a schematic diagram of an illustrative wireless power system in accordance with some embodiments.

FIG. 2 is a circuit diagram of wireless power transmitting and receiving circuitry in accordance with some embodiments.

FIG. 3 is a table of illustrative cooling capabilities for a wireless power transmitting device in accordance with some embodiments.

FIG. 4 is a diagram showing how a wireless power transmitting device may transmit cooling capabilities information to a wireless power receiving device in accordance with some embodiments.

FIG. 5 is a diagram of an illustrative data packet that may be conveyed between a wireless power transmitting device and a wireless power receiving device in accordance with some embodiments.

FIGS. 6A and 6B are diagrams of illustrative messages in a packet that includes cooling capabilities information in accordance with some embodiments.

FIG. 7 is a diagram of an illustrative extended power transmitter extended capabilities packet in accordance with some embodiments.

FIG. 8 is a flowchart of an illustrative method that may be performed by a wireless power transmitting device in accordance with some embodiments.

FIG. 9 is a flowchart of an illustrative method that may be performed by a wireless power receiving device in accordance with some embodiments.

### DETAILED DESCRIPTION

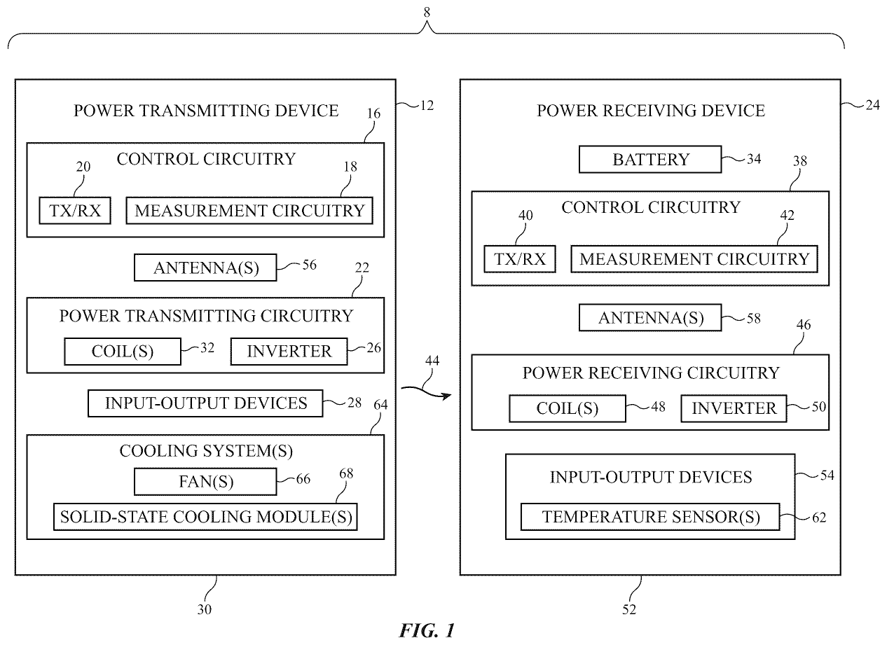

An illustrative wireless power system (also sometimes called a wireless charging system) is shown in FIG. 1. As shown in FIG. 1, wireless power system 8 may include one or more wireless power transmitting devices such as wireless power transmitting device 12 and one or more wireless power receiving devices such as wireless power receiving device 24. Wireless power system 8 may sometimes also be referred to herein as wireless power transfer (WPT) system 8 or wireless power system 8. Wireless power transmitting device 12 may sometimes also be referred to herein as power transmitter (PTX) device 12 or simply as PTX 12. Wireless power receiving device 24 may sometimes also be referred to herein as power receiver (PRX) device 24 or simply as PRX 24.

PTX device 12 includes control circuitry 16. Control circuitry 16 is mounted within housing 30. PRX device 24 includes control circuitry 38 mounted within a corresponding housing 52 for PRX device 24. Exemplary control circuitry 16 and control circuitry 38 are used in controlling the operation of WPT system 8. This control circuitry may include processing circuitry that includes one or more processors such as microprocessors, power management units, baseband processors, digital signal processors, microcontrollers, graphics processing units (GPUs), central processing units (CPUs), application processors (APs), application-specific integrated circuits with processing circuits, and/or other processing circuits. The processing circuitry implements desired control and communications features in PTX device 12 and PRX device 24. For example, the processing circuitry may be used in controlling power to one or more coils, determining and/or setting power transmission levels, generating and/or processing sensor data (e.g., to detect foreign objects and/or external electromagnetic signals or fields), controlling operation of one or more cooling systems, processing user input, handling negotiations between PTX device 12 and PRX device 24, sending and receiving in-band and out-of-band data, making measurements, and/or otherwise controlling the operation of WPT system 8.

Control circuitry in WPT system 8 (e.g., control circuitry 16 and/or 38) is configured to perform operations in WPT system 8 using hardware (e.g., dedicated hardware or circuitry), firmware and/or software. Software code for performing operations in WPT system 8 is stored on non-transitory computer readable storage media (e.g., tangible computer readable storage media) in the control circuitry of WPT system 8. The software code may sometimes be referred to as software, data, program instructions, instructions, or code. The non-transitory computer readable storage media may include non-volatile memory such as non-volatile random-access memory (NVRAM), one or more hard drives (e.g., magnetic drives or solid state drives), one or more removable flash drives or other removable media, or the like. Software stored on the non-transitory computer readable storage media may be executed on the processing circuitry of control circuitry 16 and/or 38.

PTX device 12 may be a stand-alone power adapter (e.g., a wireless charging mat or charging puck that includes power adapter circuitry), may be a wireless charging mat or puck that is connected to a power adapter or other equipment by a cable, may be an electronic device (e.g., a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a television, a computer display that does not contain an embedded computer, a gaming device, a navigation device, a wireless internet-connected voice-controlled speaker, a home entertainment device, a remote control device, a gaming controller, a peripheral user input device, a wireless base station or access point, equipment that implements the functionality of two or more of these devices, or other electronic equipment), may be equipment that has been incorporated into furniture, a vehicle, or other system, may be a removable battery case, or may be other wireless power transfer equipment.

PRX device 24 may be an electronic device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a wireless tracking tag, a television, a computer display that does not contain an embedded computer, a gaming device, a navigation device, a wireless internet-connected voice-controlled speaker, a home entertainment device, a remote control device, a gaming controller, a peripheral user input device, a wireless base station or access point, equipment that implements the functionality of two or more of these devices, or other electronic equipment.

PTX device 12 may be connected to mains power, such as a wall outlet, or an AC-to-DC adapter that is plugged into a wall outlet. Alternatively or additionally, PTX device 12 may have a battery for supplying power, and/or may have another source of power. In implementations where PTX device 12 is coupled to mains power via an external power adapter, the adapter may have an alternating-current (AC) to direct-current (DC) power converter that converts AC power from a wall outlet or other power source into DC power. If desired, PTX device 12 may include a DC-DC power converter for converting the DC power between different DC voltages. Additionally or alternatively, PTX device 12 may include an AC-DC power converter that generates the DC power from the AC power provided by the wall outlet (e.g., in implementations where PTX device 12 is connected to the wall outlet without an external power adapter). DC power may be used to power control circuitry 16. During operation, a controller in control circuitry 16 uses power transmitting circuitry 22 to transmit wireless power to power receiving circuitry 46 of PRX device 24.

Power transmitting circuitry 22 may have switching circuitry, such as inverter circuitry 26 formed from transistors, that is turned on and off based on control signals provided by control circuitry 16 to create AC current signals through one or more wireless power transmitting coils such as wireless power transmitting coil(s) 32. These coil drive signals cause coil(s) 32 to transmit wireless power. In implementations where coil(s) 32 include multiple coils, the coils may be disposed on a ferromagnetic structure, arranged in a planar coil array, or may be arranged to form a cluster of coils (e.g., two or more coils, 5-10 coils, at least 10 coils, 10-30 coils, fewer than 35 coils, fewer than 25 coils, or other suitable number of coils). In some implementations, PTX device 12 includes only a single coil 32.

As the AC currents pass through one or more coils 32, alternating-current electromagnetic (e.g., magnetic) fields (wireless power signals 44) are produced that are received by one or more corresponding receiver coils such as coil(s) 48 in PRX device 24. In other words, one or more of coils 32 is inductively coupled to one or more of coils 48. PRX device 24 may have a single coil 48, at least two coils 48, at least three coils 48, at least four coils 48, or another suitable number of coils 48. When the alternating-current electromagnetic fields are received by coil(s) 48, corresponding alternating-current currents are induced in coil(s) 48. The AC signals that are used in transmitting wireless power may have any desired frequency (e.g., 100-400 kHz, 1-100 MHz, between 1.7 MHz and 1.8 MHz, less than 2 MHz, between 100 kHz and 2 MHz, between 100 kHz and 15 MHz, 6.78 MHz, 13.56 MHz, etc.). Rectifier circuitry such as rectifier circuitry 50, which contains rectifying components such as synchronous rectification transistors arranged in a bridge network, converts received AC signals (received alternating-current signals associated with wireless power signals 44) from one or more coils 48 into DC voltage signals for powering PRX device 24. Wireless power signals 44 are sometimes referred to herein as wireless power 44 or wireless charging signals 44. Coils 32 are sometimes referred to herein as wireless power transfer coils 32, wireless charging coils 32, or wireless power transmitting coils 32. Coils 48 are sometimes referred to herein as wireless power transfer coils 48, wireless charging coils 48, or wireless power receiving coils 48.

The DC voltage produced by rectifier circuitry 50 (sometime referred to as rectifier output voltage Vrect) may be used in charging a battery such as battery 34 and may be used in powering other components in PRX device 24 such as control circuitry 38, input-output (I/O) devices 54, etc. PTX device 12 may also include input-output devices such as input-output devices 28. Input-output devices 54 and/or input-output devices 28 may include input devices for gathering user input and/or making environmental measurements and may include output devices for providing a user with output.

As examples, input-output devices 28 and/or input-output devices 54 may include a display (screen) for creating visual output, a speaker for presenting output as audio signals, light-emitting diode status indicator lights and other light-emitting components for emitting light that provides a user with status information and/or other information, haptic devices for generating vibrations and other haptic output, and/or other output devices. Input-output devices 28 and/or input-output devices 54 may also include sensors for gathering input from a user and/or for making measurements of the surroundings of WPT system 8.

FIG. 1 shows an example where input-output devices 54 in PRX 24 include one or more temperature sensors 62. The temperature sensor(s) may measure temperatures associated with the environment of PRX 24 and/or the temperature of PRX 24 itself. As one illustrative example, at least one temperature sensor may be positioned to measure a temperature of an exterior surface of housing 52 and at least one temperature sensor may be positioned to measure a temperature of battery 34 (within the interior of PRX 24).

The example in FIG. 1 of PRX device 24 including battery 34 is illustrative. More generally, an electronic device may include a power storage device 34. Power storage device 34 may be a battery, or may be, for example, a supercapacitor that stores charge.

PTX device 12 and PRX device 24 may communicate wirelessly using in-band or out-of-band communications. Implementations using in-band communication may utilize, for example, frequency-shift keying (FSK) and/or amplitude-shift keying (ASK) techniques to communicate in-band data between PTX device 12 and PRX device 24. Wireless power and in-band data transmissions may be conveyed using coils 32 and 48 concurrently. When PTX 12 sends in-band data to PRX 24, wireless transceiver (TX/RX) circuitry 20 may modulate wireless charging signal 44 to impart FSK or ASK communications, and wireless transceiver circuitry 40 may demodulate the wireless charging signal 44 to obtain the data that is being communicated. When PRX 24 sends in-band data to PTX 12, wireless transceiver (TX/RX) circuitry 40 may modulate wireless charging signal 44 to impart FSK or ASK communications, and wireless transceiver circuitry 20 may demodulate the wireless charging signal 44 to obtain the data that is being communicated.

Implementations using out-of-band communication may utilize, for example, hardware antenna structures and communication protocols such as Bluetooth or NFC to communicate out-of-band data between PTX device 12 and PRX device 24. Power may be conveyed wirelessly between coils 32 and 48 concurrently with the out-of-band data transmissions. Wireless transceiver circuitry 20 may wirelessly transmit and/or receive out-of-band signals to and/or from PRX device 24 using an antenna such as antenna 56. Wireless transceiver circuitry 40 may wirelessly transmit and/or receive out-of-band signals to and/or from PTX device 12 using an antenna such as antenna 58.

Control circuitry 16 in PTX device 12 has measurement circuitry 18 that may be used to perform measurements of one or more characteristics external to PTX device 12. For example, measurement circuitry 18 may detect external objects on or adjacent the charging surface of the housing of PTX device 12. While shown in FIG. 1 as being separate from power transmitting circuitry 22 for the sake of clarity, measurement circuitry 18 may form a part of power transmitting circuitry 22 if desired.

Measurement circuitry 18 may detect foreign objects such as coils, paper clips, and other metallic objects, may detect the presence of PRX device 24 (e.g., circuitry 18 may detect the presence of one or more coils 48 and/or magnetic core material associated with coils 48), and/or may detect the presence of other power transmitting devices in the vicinity of PTX device 12 and/or WPT system 8. Measurement circuitry 18 may also be used to make sensor measurements using a capacitive sensor, may be used to make temperature measurements, and/or may otherwise be used in gathering information indicative of whether a foreign object, power transmitting device, power receiving device, or other external object (e.g., PRX device 24) is present on or adjacent to the coil(s) 32 of PTX device 12. If desired, PRX device 24 may include measurement circuitry 42. Measurement circuitry 42 may perform one or more of the measurements performed by measurement circuitry 18 (e.g., for or using coil(s) 48 on PRX device 24).

As shown in FIG. 1, PTX 12 may include one or more cooling system(s) 64. The cooling systems are configured to cool one or more portions of PTX 12. The cooling systems may cool the temperature of a charging surface of housing 30 in PTX 12. When PRX 24 is resting on the charging surface, cooling the charging surface may also cool PRX 24.

Cooling systems 64 may include one or more fans 66. Each fan may be individually adjusted by control circuitry 16 to adjust the total cooling applied by colling systems 64. Each fan may have a maximum speed (with an associated maximum cooling effect), a minimum speed (e.g., when the fan is turned off and there is no associated cooling effect), and one or more intermediate speeds. As a specific example, a fan may be operable in four states: an off state where the fan does not spin, a low state where the fan spins at a first rate and provides a first cooling effect, a medium state where the fan spins at a second rate and provides a second cooling effect, and a high state where the fan spins at a third rate and provides a third cooling effect. The second rate may be greater than the first rate and the third rate may be greater than the second rate. The second cooling effect may be greater than the first cooling effect and the third cooling effect may be greater than the second cooling effect.

Cooling systems 64 may include one or more solid-state cooling modules 68. The solid-state cooling modules may comprise a thermoelectric heat pump (sometimes referred to as a Peltier cooler, Peltier device, solid-state refrigerator, thermoelectric cooler, etc.) that transfers heat with consumption of electrical energy. Each solid-state cooling module may be operable in different states with different corresponding cooling levels.

The examples of cooling systems provided herein are merely illustrative. In general, PTX 12 may include any desired type(s) of cooling systems.

Each one of housing 30 and housing 52 may be formed from plastic, metal, fiber-composite materials such as carbon-fiber materials, wood and other natural materials, glass, other materials, and/or combinations of two or more of these materials.

The example in FIG. 1 of PTX 12 transmitting wireless power and PRX 24 receiving wireless power is merely illustrative. PTX 12 may optionally be capable of receiving wireless power signals using coil(s) 32 and PRX 24 may optionally be capable of transmitting wireless power signals using coil(s) 48. When a device is capable of both transmitting and receiving wireless power signals, the device may include both an inverter and a rectifier.

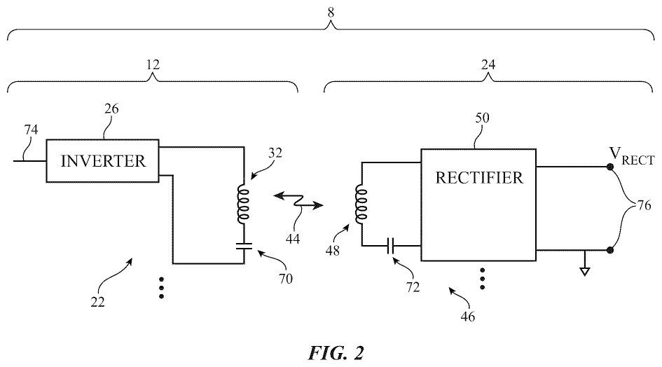

FIG. 2 is a circuit diagram of illustrative wireless charging circuitry for system 8. As shown in FIG. 2, circuitry 22 may include inverter circuitry such as one or more inverters 26 or other drive circuitry that produces wireless power signals that are transmitted through an output circuit that includes one or more coils 32 and capacitors such as capacitor 70. In some embodiments, device 12 may include multiple individually controlled inverters 26, each of which supplies drive signals to a respective coil 32. In other embodiments, an inverter 26 is shared between multiple coils 32 using switching circuitry.

During operation, control signals for inverter(s) 26 are provided by control circuitry 16 at control input 74. A single inverter 26 and single coil 32 is shown in the example of FIG. 2, but multiple inverters 26 and multiple coils 32 may be used, if desired. In a multiple coil configuration, switching circuitry (e.g., multiplexer circuitry) may be used to couple a single inverter 26 to multiple coils 32 and/or each coil 32 may be coupled to a respective inverter 26.

During wireless power transmission operations, transistors in one or more selected inverters 26 are driven by AC control signals from control circuitry 16. The relative phase between the inverters may be adjusted dynamically (e.g., a pair of inverters 26 may produce output signals in phase or out of phase).

The application of drive signals using inverter(s) 26 (e.g., transistors or other switches in circuitry 22) causes the output circuits formed from selected coils 32 and capacitors 70 to produce alternating-current electromagnetic fields (signals 44) that are received by wireless power receiving circuitry 46 using a wireless power receiving circuit formed from one or more coils 48 and one or more capacitors 72 in device 24.

Rectifier circuitry 50 is coupled to one or more coils 48 and converts received power from AC to DC and supplies a corresponding direct current output voltage Vrect across rectifier output terminals 76 for powering load circuitry in device 24 (e.g., for charging battery 34, for powering a display and/or other input-output devices 54, and/or for powering other components).

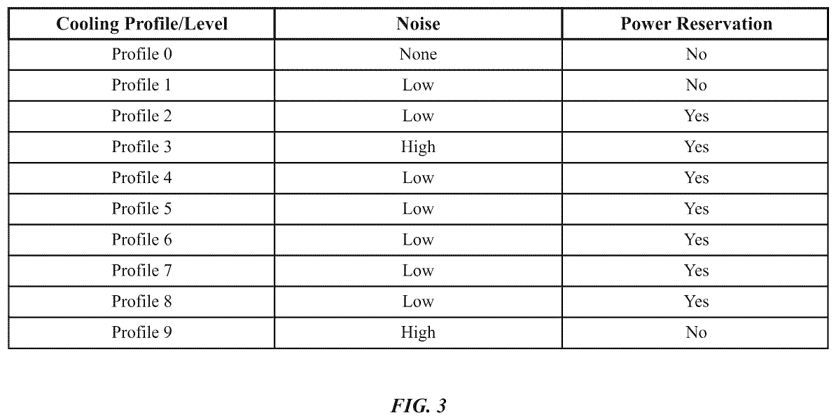

Cooling system(s) 64 in PTX 12 may be operable in a number of different configurations, each configuration having its own respective characteristics. FIG. 3 is a table of illustrative cooling system configurations. Each cooling system configuration may be referred to as a cooling profile. In the example of FIG. 3, cooling system(s) 64 are operable in ten unique profiles: profile 0, profile 1, profile 2, etc. The magnitude of cooling effect provided by each cooling profile may increase with increasing profile number. In other words, profile 1 provides more cooling effect than profile 0, profile 2 provides more cooling effect than profile 1, profile 3 provides more cooling effect than profile 2, etc. The profile number is therefore also indicative of the cooling level associated with that profile (with higher profile numbers having greater cooling levels).

As shown by the table of FIG. 3, each cooling profile may have corresponding noise information and power sacrifice information. The noise information is indicative of the audible noise generated by cooling system(s) 64 while the cooling system(s) operates according to that cooling profile. The power sacrifice information, which may also be referred to as power reservation information, is indicative of whether power transmitting circuitry 22 has to reduce its transmitted power when cooling system(s) 64 operates using that cooling profile, such that power is reserved for cooling system operation.

As examples of cooling profiles, consider an example where PTX 12 includes two fans and a solid-state cooling module. In a first cooling profile, one of the two fans may be turned on to a low speed, one of the two fans may be turned off, and the solid-state cooling module may be turned off. In a second cooling profile with a greater cooling effect than the first cooling profile, both fans may be turned on to a low speed and the solid-state cooling module may be turned off. In a third cooling profile with a greater cooling effect than the second cooling profile, one of the two fans may be turned on to a low speed, one of the two fans may be turned on to a high speed, and the solid-state cooling module may be turned off. In a fourth cooling profile with a greater cooling effect than the third cooling profile, both fans may be turned on to a high speed and the solid-state cooling module may be turned off. In a fifth cooling profile with a greater cooling effect than the fourth cooling profile, one of the two fans may be turned on to a low speed, one of the two fans may be turned off, and the solid-state cooling module may be turned on. In a sixth cooling profile with a greater cooling effect than the fifth cooling profile, both fans may be turned on to a low speed and the solid-state cooling module may be turned on. In a seventh cooling profile with a greater cooling effect than the sixth cooling profile, one of the two fans may be turned on to a low speed, one of the two fans may be turned on to a high speed, and the solid-state cooling module may be turned on. In an eighth fourth cooling profile with a greater cooling effect than the seventh cooling profile, both fans may be turned on to a high speed and the solid-state cooling module may be turned on.

Operating a fan at a higher speed will be noisier than operating a fan at a lower speed. Similarly, operating more fans will be noisier than operating less fans. Some cooling systems such as solid-state cooling module(s) 68 may be relatively quiet (whether turned on or turned off). The noise characteristics associated with each cooling profile may be indicative of how detectable the noise from the cooling system(s) will be relative to ambient noise in the surrounding environment of PTX 12. The noise characteristic of cooling system(s) 64 when all of the cooling system(s) are turned off may be none (e.g., no noise is generated by the cooling systems when they are turned off). In a quiet room, the noise characteristic of cooling system(s) 64 when one fan is turned on a low speed may be low. In a quiet room, the noise characteristic of cooling system(s) 64 when two fans are turned on a high speed may be high. In a noisy environment, the ambient noise may drown out noise from cooling system(s) 64. In a noisy environment, the noise characteristic of cooling system(s) 64 when one fan is turned on a low speed may be none (e.g., no audible noise is generated relative to the noisy environment by one fan at the low speed). In a noisy environment, the noise characteristic of cooling system(s) 64 when two fans are turned on a high speed may be low (e.g., a low audible noise is generated relative to the noisy environment by two fans at the high speed).

The noise characteristic therefore may comprise perceived noise associated with the cooling profile (factoring in the ambient noise) and/or may comprise noise associated with the cooling profile independent of ambient noise.

Operating more fans and/or solid-state cooling modules may require more power consumption than operating less fans and/or solid-state cooling modules (e.g., turning on 3 fans requires more power than turning on 1 fan). Similarly, operating a single cooling system to have a high cooling effect may require more power consumption than operating the cooling system to have a low cooling effect (e.g., running a fan on a high speed requires more power than running the fan on a low speed). The greater the power consumption of cooling system(s) 64, the more likely that PTX 12 needs to reserve the power transmitted by power transmitting circuitry 22 to PRX 24. For example, PTX 12 may, when no cooling systems are turned on, deliver 15 W of power to PRX 24. When the cooling systems operate according to a first cooling profile, PTX 12 may continue to deliver 15 W of power to PRX 24 (e.g., no power needs to be reserved). When the cooling systems operate according to a second cooling profile, PTX 12 may deliver 14 W of power to PRX 24 (e.g., 1 W of power needs to be reserved). When the cooling systems operate according to a third cooling profile, PTX 12 may deliver 12 W of power to PRX 24 (e.g., 3 W of power needs to be reserved).

The power reservation associated with each cooling profile may be dependent on real time operating conditions of PTX 12. For example, PTX 12 may not need to reserve any power for the first, second, or third cooling profiles when PTX 12 is connected to mains power (e.g., a wall outlet). However, when PTX 12 is not connected to mains power (and is operating using battery power), PTX 12 may need to reserve power for the second and third cooling profiles.

During operation of wireless charging system 8, PTX 12 may transmit cooling capabilities information to PRX 24. The cooling capabilities information may identify cooling profiles and corresponding cooling level information, noise information, and/or power reservation information. As an example, the cooling capabilities information transmitted from PTX 12 to PRX 24 may include the information of the table of FIG. 3. In response to receiving the cooling capabilities information from PTX 12, PRX 24 may select one of the profiles identified in the cooling capabilities information and transmit the selection (sometimes referred to as the request) to PTX 12. PTX 12 may then operate cooling system(s) 64 using the cooling profile requested by PRX 24.

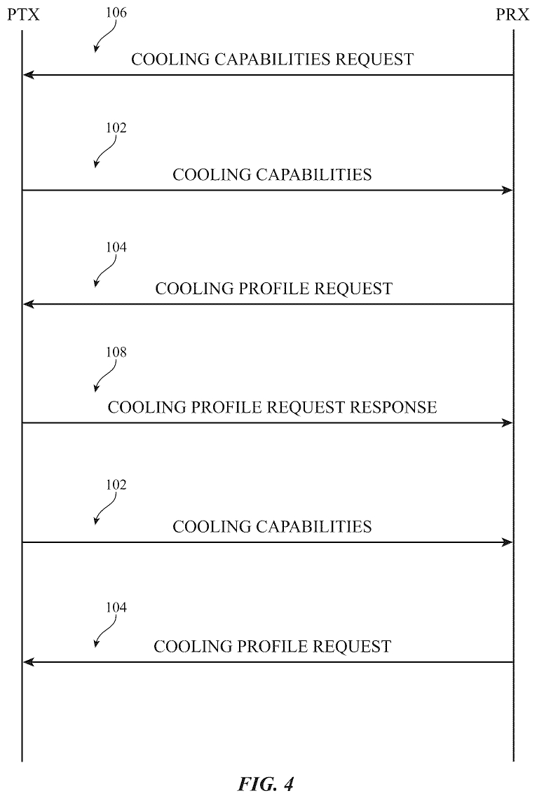

FIG. 4 is a flowchart showing how PTX 12 may transmit cooling capabilities information to PRX 24. As shown in FIG. 4, PRX 24 may optionally transmit a packet 106 to PTX 12. The packet 106 (sometimes referred to as a cooling capabilities request packet or GET_COOLING_INFO packet) may serve as a request from PRX 24 for PTX 12 to transmit cooling capabilities information to PRX 24. Packet 106 may optionally be omitted and PTX 12 may automatically send cooling capabilities information to PRX 24 at regular intervals and/or in response to a change in the cooling capabilities of PTX 12.

PTX 12 may transmit a packet 102 to PRX 24. The packet 102 (sometimes referred to as a cooling capabilities packet or COOLING_CAP packet) may identify a number of cooling profiles with corresponding cooling level information, noise information, and/or power reservation information. PRX 24 receives the cooling capabilities packet 102 and selects one of the profiles identified in the cooling capabilities information. PRX 24 may then transmit a packet 104 (sometimes referred to as cooling profile request packet 104 or SET_COOLING_PARAM packet 104) to PTX 12 that identifies the requested profile of the profiles identified in the cooling capabilities information. In response to receiving the cooling profile request packet 104, PTX 12 may optionally send a response packet 108 (sometimes referred to as cooling profile request response packet 108 or RSP_COOLING_PARAM packet 108) to confirm whether or not the requested cooling profile has been implemented by PTX 12.

As shown in FIG. 4, the process of PTX 12 transmitting a cooling capabilities packet 102 to PRX 24 and PRX 24 responding with a cooling profile request packet 104 may be repeated. PRX 24 may respond with a cooling profile request packet 104 each time the cooling capabilities packet 102 is received at PRX 24. PRX 24 may optionally receive a cooling capabilities packet 102 and choose to take no further action (e.g., PRX 24 does not send a cooling profile request packet 104 in response to receiving the cooling capabilities packet 102). PTX 12 may transmit the cooling capabilities packet 102 at regular intervals, when there is a change to the cooling capabilities information included in the cooling capabilities packet, and/or in response to receiving a cooling capabilities request packet 106 from PRX 24.

As an example, characteristics of the cooling profiles may change when PTX 12 is connected to mains power (e.g., an AC-to-DC adapter that is plugged into a wall outlet). PTX 12 may transmit a first cooling capabilities packet before PTX 12 is connected to mains power. In response to PTX 12 being connected to mains power, PTX 12 may transmit a second cooling capabilities packet with updated cooling profile information that accounts for the PTX being connected to the mains power.

Each one of packets 102, 104, 106, and 108 may include numerous data bits (sometimes referred to as bits). The data bits may be grouped into bytes, with each byte including any desired number of bits (e.g., 8 bits). Each one of packets 102, 104, 106, and 108 may be transmitted using in-band communication.

Data packets may be transmitted between devices 12 and 24 in a data stream. There are many types of data that may be transmitted between a wireless power transmitting device and a wireless power receiving device. As shown in connection with FIG. 4, the data transmitted between a wireless power transmitting device and a wireless power receiving device may include cooling capabilities information and/or a cooling profile request. Additionally, transmitted data may include authentication data, a firmware update, a command, configuration data, power data (e.g., received power levels, states of charge, etc.) or any other desired type of data. There are numerous types of data packets that may be transmitted during operation of one or more data streams. Auxiliary data control (ADC) packets may be used to open and close (activate and deactivate) data streams. Auxiliary data transport (ADT) packets may be used to transmit data using an active data stream. Data stream response (DSR) packets may allow acknowledgments to be transmitted upon successful receipt of data. All of these types of packets may optionally include a stream header or other stream identifying information.

In some communication schemes, there may only be one active data stream per communication direction using in-band communication between devices 12 and 24. This limits the devices to transmitting only one type of data at a time. Data packets may be transmitted using the data stream until all of the pertinent data packets have been successfully transmitted. After the transmission is complete, transmission of additional packets of a different type may begin. Alternatively, to increase flexibility of data communication, a communication scheme may be used that allows for multiple active data streams. This allows for more control over the transmission of different types of information. As an example, a first data stream with a first type of data may be paused and a second type of data may be transmitted using a second data stream. Once the second type of data is transmitted, the transmission of the first type of data using the first data stream may be resumed.

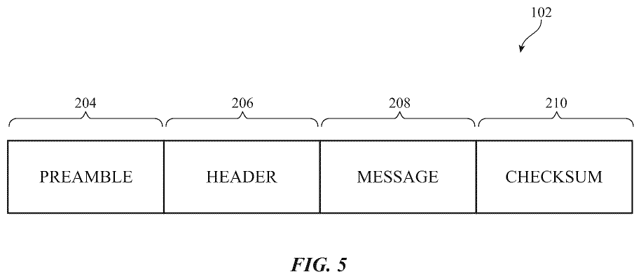

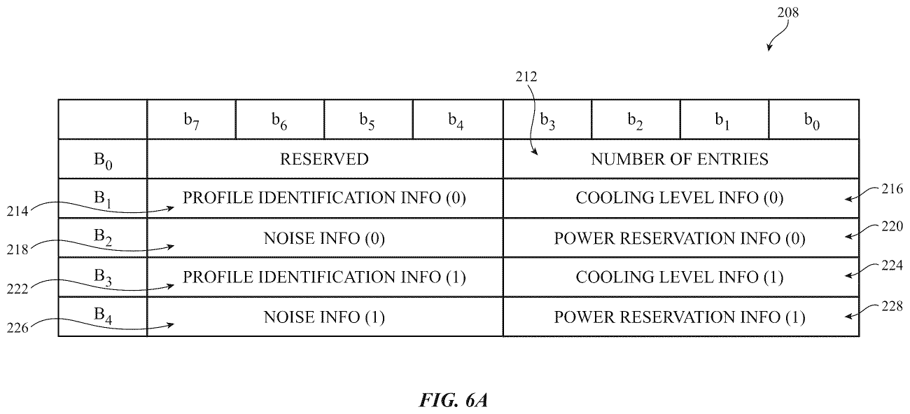

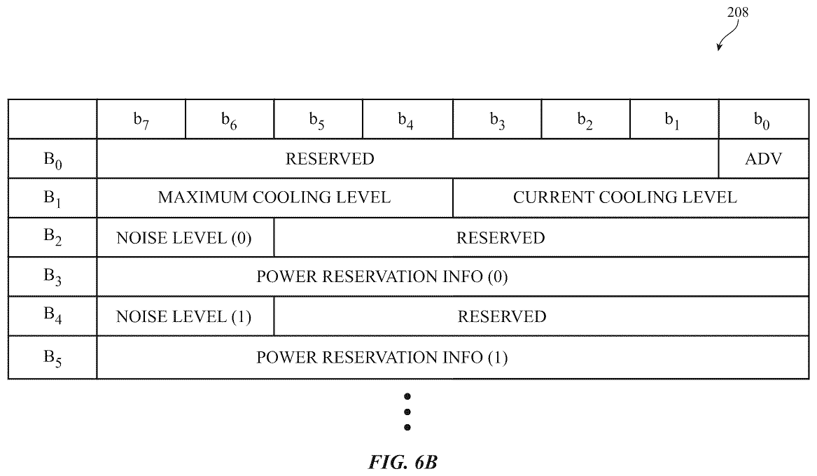

FIG. 5 is a diagram of an illustrative data packet that includes cooling capabilities information. As shown in FIG. 5, packet 102 may include a preamble 204 (e.g., a preamble byte), header 206 (e.g., a header byte), message 208 (e.g., one or more message bytes), and checksum 210 (e.g., a checksum byte). Preamble 204 may include a sequence of bits that enables the data-packet-receiving-device to accurately detect the start bit of the header. Header 206 may indicate the type of packet that is being transmitted. In instances where the packet is a cooling capabilities packet, the header may identify the packet as a data packet that provides cooling capabilities information. Message 208 (sometimes referred to as payload 208) includes the data that is desired to be transmitted. In instances where the packet is a cooling capabilities packet, message 208 may include the cooling capabilities information (as is shown in more detail in connection with FIG. 6A). Checksum 210 allows for verification that the entire packet was transmitted successfully. The device receiving the packet may calculate a checksum value for the packet and compare the calculated checksum value to a target checksum value received in the checksum byte. If the calculated checksum value and the target checksum value match, the packet is interpreted as being transmitted successfully. If the calculated checksum value and the target checksum value do not match, the packet transmission is interpreted as including an error.

In communication schemes with multiple concurrently active data streams, packet 102 may include an optional stream header that identifies a corresponding stream number for the data packet. The stream header may be transmitted after header 206 but before message 208 or at another desired position within the packet.

FIG. 6A is a diagram of illustrative message bytes 208 for cooling capabilities packet 102 of FIG. 5. As shown, message 208 includes five bytes (B₀, B₁, B₂, B₃, B₄,), each byte having eight bits (b₀, b₁, etc.). This example is merely illustrative and in general packet 102 may include any desired number of bytes and any desired number of bits per byte. Message 208 may include one or more bits 212 that represent the number of entries/profiles in cooling capabilities packet 102. For example, when PTX 12 has 10 possible cooling profiles as in the example of FIG. 3, the one or more bits 212 may indicate a magnitude of 10 (for 10 corresponding profiles).

Subsequent bits in message 208 may convey characteristics of each one of the profiles. As shown in FIG. 6A, one or more bits 214 may identify a first profile such as profile 0. One or more bits 216 may identify a cooling level associated with the first profile. One or more bits 218 may identify a noise level associated with the first profile. One or more bits 220 may identify a power reservation level associated with the first profile.

Profile identification information 214 may simply identify a particular cooling profile. When PRX 24 selects one of the cooling profiles in cooling profile request packet 104, the cooling profile request packet may include one or more bits that identify the profile identification information 214 associated with the selected profile. The example in FIG. 6A of using 4 bits to convey the profile identification information is merely illustrative. In general, the profile identification information 214 may have any desired format and may include any desired number of bits.

Cooling level information 216 may identify a cooling level associated with a particular cooling profile. The cooling level may be a rank of the cooling level of that profile relative to the other profiles, may be a quantification of cooling for that profile relative to a maximum possible cooling level, may be a magnitude of cooling capacity, may be a coarse characterization of cooling level (e.g., low, medium, or high), etc.

In the example of FIG. 3, the cooling profiles are ordered by cooling level, with profile 0 having the lowest corresponding cooling level and profile 9 having the highest corresponding cooling level. In this type of example, the profile number also serves as the cooling level information for that profile. When the profile number also serves as the cooling level information for each profile, profile identification bits 214 and cooling level bits 216 are duplicative and either profile identification bits 214 or cooling level bits 216 may be omitted from message 208. When the profile number also serves as the cooling level information for each profile, the profile identification information may be referred to as profile identification and cooling level information.

In another example, cooling level information 216 may include a quantification of cooling for that profile relative to a maximum possible cooling level. Consider the example of FIG. 3 where there are 10 possible cooling profiles. The profile with the maximum cooling level (e.g., profile 9 in FIG. 3) may be defined as having a cooling level of 100% of the maximum cooling level. The cooling levels of the other profiles may be defined as percentages relative to the maximum cooling level. For example, a first cooling profile may have a cooling level that is 26% the maximum cooling level, a second cooling profile may have a cooling level that is 32% the maximum cooling level, a third cooling profile may have a cooling level that is 47% the maximum cooling level, etc. This type of scheme for conveying cooling level information therefore has more detailed cooling level information than only conveying cooling level rankings as in the example of FIG. 3.

In another example, cooling level information 216 may include a coarse characterization of cooling level. The cooling level information may include two bits, with a 00 value indicative of no cooling, a 01 value indicative of low cooling, a 10 value indicative of medium cooling, and a 11 value indicative of high cooling. This example is merely illustrative and more bits may be used to increase the granularity of the cooling level information if desired.

The example in FIG. 6A of using 4 bits to convey the cooling level information is merely illustrative. In general, the cooling level information 216 may have any desired format and may include any desired number of bits.

Noise information 218 may identify a noise level associated with a particular cooling profile. The noise level may be a rank of the noise level of that profile relative to the other profiles, may be a quantification of noise for that profile relative to a maximum possible noise level, may be a magnitude of noise (e.g., in decibels), may be a coarse characterization of noise level (e.g., low, medium, or high), etc.

As an example, the cooling profiles may be ordered/ranked by noise level. The noise information may identify the noise level of the profile relative to the other profiles. In the example where there are ten possible profiles, a noise level of 0 has the lowest corresponding noise level and a noise level of 9 has the highest corresponding noise level.

In another example, noise information 218 may include a quantification of noise level for that profile relative to a maximum noise level. The profile with the maximum noise level may be defined as having a noise level of 100% of the maximum noise level. The noise levels of the other profiles may be defined as percentages relative to the maximum noise level. For example, a first cooling profile may have a noise level that is 26% the maximum noise level, a second cooling profile may have a noise level that is 32% the maximum noise level, a third cooling profile may have a noise level that is 47% the maximum noise level, etc. This type of scheme for conveying noise level information therefore has more detailed noise level information than only conveying noise level ranking as in the previous example.

In another example, noise information 218 may include a coarse characterization of noise level. The noise level information may include two bits, with a 00 value indicative of no noise, a 01 value indicative of low noise, a 10 value indicative of medium noise, and a 11 value indicative of high noise. This example is merely illustrative and more bits may be used to increase the granularity of the noise level information if desired.

The example in FIG. 6A of using 4 bits to convey the noise level information is merely illustrative. In general, the noise information 218 may have any desired format and may include any desired number of bits.

Power reservation information 220 may identify a power reservation level associated with a particular cooling profile. The power reservation level may be a rank of the power reservation level of that profile relative to the other profiles, may be a quantification of power reservation for that profile relative to a maximum possible power reservation level, may be a magnitude of power reservation (e.g., in Watts), may be a coarse characterization of power reservation level (e.g., low, medium, or high), etc.

As an example, the cooling profiles may be ordered/ranked by power reservation level. The power reservation information may identify the power reservation level of the profile relative to the other profiles. In the example where there are ten possible profiles, a power reservation level of 0 has the lowest corresponding power reservation level and a power reservation level of 9 has the highest corresponding power reservation level.

In another example, power reservation information 220 may include a quantification of power reservation level for that profile relative to a maximum power reservation level. The profile with the maximum power reservation level may be defined as having a power reservation level of 100% of the maximum power reservation level. The power reservation levels of the other profiles may be defined as percentages relative to the maximum power reservation level. For example, a first cooling profile may have a power reservation level that is 26% the maximum power reservation level, a second cooling profile may have a power reservation level that is 32% the maximum power reservation level, a third cooling profile may have a power reservation level that is 47% the maximum power reservation level, etc. This type of scheme for conveying power reservation level information therefore has more detailed power reservation level information than only conveying a power reservation level ranking as in the previous example.

In another example, power reservation information 220 may include a coarse characterization of power reservation level. The power reservation level information may include two bits, with a 00 value indicative of no power reservation, a 01 value indicative of low power reservation, a 10 value indicative of medium power reservation, and a 11 value indicative of high power reservation. This example is merely illustrative and more bits may be used to increase the granularity of the power reservation level information if desired.

The example in FIG. 6A of using 4 bits to convey the power reservation information is merely illustrative. In general, the power reservation information 220 may have any desired format and may include any desired number of bits.

Message 208 may include, for each subsequent cooling profile, corresponding profile identification bits, corresponding cooling level bits, corresponding noise level bits, and corresponding power reservation bits. As shown in FIG. 6A, one or more bits 222 may identify a second profile such as profile 1, one or more bits 224 may identify a cooling level associated with the second profile, one or more bits 226 may identify a noise level associated with the second profile, one or more bits 228 may identify a power reservation level associated with the second profile, etc.

Cooling profile request packet 104, cooling capabilities request packet 106, and cooling profile request response 108 may have the packet structure shown in FIG. 5 or any other desired packet structure. The cooling profile request packet 104 may include one or more bits that identify one of the cooling profiles that is included in cooling capabilities packet 102. The cooling profile request response packet 108 may include one or more bits that indicate whether the requested cooling profile was successfully implemented by PTX 12. For example, the cooling profile request response packet 108 may include a bit that has a value of ‘0’ to indicate that the requested cooling profile was successfully implemented by PTX 12 and a value of ‘1’ to indicate that the requested cooling profile was not successfully implemented by PTX 12 (e.g., if the requested cooling profile is not supported by PTX 12).

It is noted that PRX 24 may transmit a dedicated cooling profile request packet 104 as shown in the example of FIG. 4. Alternatively, the cooling profile selected by PRX 24 may be identified in a packet that includes other information. For example, the cooling profile selected by PRX 24 may be identified in a received power (RP) packet that also includes information identifying a received power level at PRX 24, a control error (CE) packet that also includes feedback about a desired power level for PRX 24, a configuration (CFG) packet that also provides configuration data from PRX 24 to PTX 12, etc.

FIG. 6A shows one arrangement for illustrative message bytes 208 for cooling capabilities packet 102 of FIGS. 4 and 5. However, this example is merely illustrative and other types of message bytes may be included in the cooling capabilities packet if desired. FIG. 6B is another possible arrangement for message 208 for cooling capabilities packet 102 of FIGS. 4 and 5.

In the example of FIG. 6B, byte 1 (B₁) includes four bits that identify the maximum cooling level available for PTX 12. As an example, PTX 12 may have 16 available cooling levels identified by the integers between 0 and 15. The first four bits of byte 1 identify the maximum cooling level available for PTX 12 (e.g., cooling level 15). The final four bits of byte 1 identify the current cooling level being used by PTX 12 (e.g., cooling level 7).

The cooling capabilities packet may optionally identify additional details about each cooling level if desired. In the example of FIG. 6B, two bytes are used to identify additional details about each cooling level. Bytes B₂ and B₃ are used to identify additional details about cooling profile 0, bytes B₄ and B₅ are used to identify additional details about cooling profile 1, etc.

In the example of FIG. 6B, the additional details for each cooling level may include two noise level bits and a byte with power reservation information. The two noise level bits may identify the noise level associated with that cooling profile. A value of ‘0’ (identified by bits 00) may be associated with no noise. A value of ‘1’ (identified by bits 01) may be associated with low noise. A value of ‘2’ (identified by bits 10) may be associated with medium noise. A value of ‘3’ (identified by bits 11) may be associated with high noise. The power reservation information may include the magnitude of possible power reduction (in units of mW) associated with operating PTX 12 at the respective cooling level.

In the example of FIG. 6B, the cooling capabilities packet includes noise level information and power reservation information for each one of the available cooling profiles. This example is merely illustrative and the length of the cooling capabilities packet may optionally be reduced by omitting the additional details regarding noise level information and power reservation information. When the additional details regarding noise level information and power reservation information are omitted, bytes B₂-B₅ (and subsequent bytes with the additional details) may be omitted from message 208.

In some communication protocols, PTX 12 may always transmit a cooling capabilities packet that includes the additional details of byte B₂ and onwards in FIG. 6B. In some communication protocols, PTX 12 may always transmit a cooling capabilities packet that does not include the additional details of byte B₂ and onwards in FIG. 6B. In some communication protocols, PTX 12 may sometimes transmit a cooling capabilities packet that includes the additional details of byte B₂ and onwards in FIG. 6B and may sometimes transmit a cooling capabilities packet that does not include the additional details of byte B₂ and onwards in FIG. 6B. To enable PTX 12 to switch between the two packet lengths with different levels of detail, the cooling capabilities packet may include one or more bits (e.g., bit b₀ of byte B₀ in FIG. 6B) that identify whether additional details are included for the cooling profiles.

Bit b₀ of byte B₀ in FIG. 6B identifies whether or not the packet is in an advanced mode or not and may sometimes be referred to as an advanced mode bit. When the advanced mode bit has a value of 0, message 208 may only include bytes B₀-B₁ in FIG. 6B (without the additional details for each cooling profile). When the advanced mode bit has a value of 1, message 208 may include bytes B₂ and onward in FIG. 6B (with the additional details for each cooling profile).

When PTX 12 and PRX 24 initiate communications with one another, PTX 12 and PRX 24 may communicate in configuration, handshake, and/or negotiation phases before commencing a power transfer phase. During the configuration, handshake, and/or negotiation phases, PTX 12 may transmit information about the PTX's capabilities to PRX 24. As a specific example, PTX 12 may transmit an extended power transmitter extended capabilities (ECAP) packet to PRX 24. PTX 12 may optionally transmit the ECAP packet in response to receiving an ECAP request packet from PRX 24.

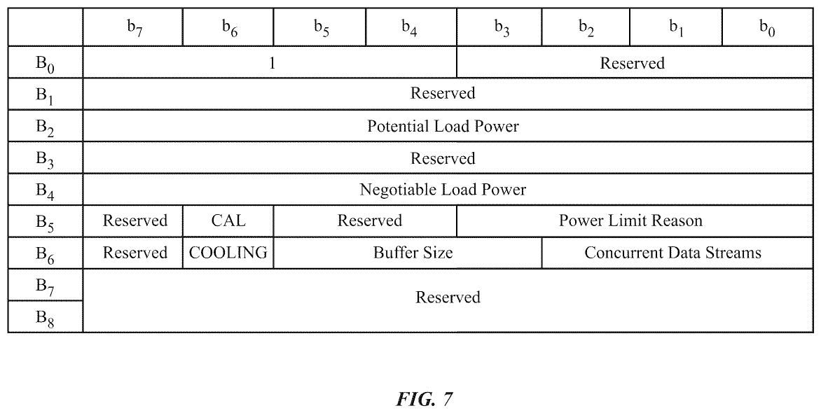

FIG. 7 is a diagram of the message of an illustrative extended power transmitter extended capabilities (ECAP) packet. As shown in FIG. 7, the ECAP packet may include a byte with potential load power information. The potential load power information may be set to the maximum potential load power that may be supported by PTX 12 (e.g., in 100 mW units). The ECAP packet may include negotiable load power information. The negotiable load power information may include the maximum available potential load power that PRX 24 is allowed to negotiate (e.g., in 100 mW units).

The power limit reason may be one or more bits indicating a reason for the power limit. For example, when the negotiable load power is less than the potential load power, the power limit reason indicates the reason for the lower negotiable load power. Each power limit reason may be assigned a respective value between 0 and 15. As illustrative examples, the value may be 0 when there is no limit, the value may be 2 to indicate a possible foreign object presence, the value may be 3 to indicate brown-out protection, the value may be 4 to indicate over temperature, the value may be 6 to indicate over current, the value may be 7 to indicate maximum available power, the value may be 8 to indicate power modes, the value may be 10 to indicate a calibration requirement has not been met, the value may be 11 to indicate a calibration limit, and the value may be 12 to indicate cooling control. The cooling control value therefore indicates the negotiable load power is less than the potential load power due to power requirements for ongoing cooling control.

The ECAP packet may also include one or more bits (such as the COOLING bit in FIG. 7) that identify whether or not PTX 12 supports a cooling control data stream. The COOLING bit may have a value of 0 when PTX 12 does not support the cooling control data stream. The COOLING bit may have a value of 1 when PTX 12 does support the cooling control data stream.

The buffer size bit(s) indicate the size of the data stream buffer. The number of bytes in the buffer may be equal to 16×2^{N}, with the N-value contained in the buffer size field. The concurrent data streams bit(s) indicate the maximum number of concurrent data streams the power transmitter can handle.

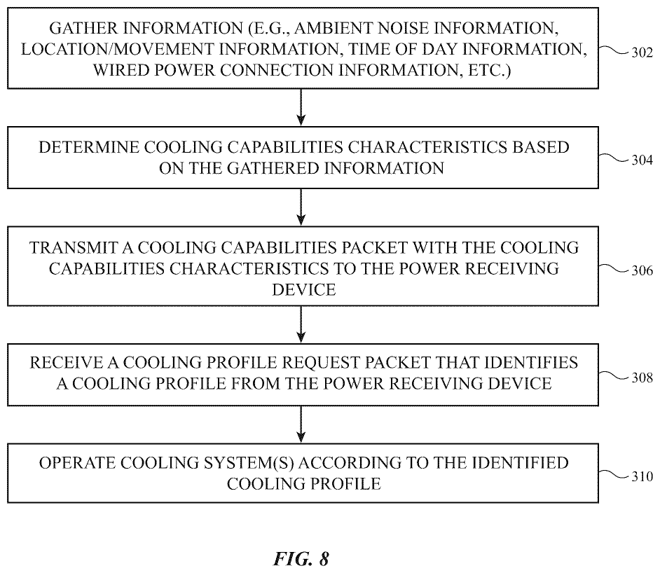

FIG. 8 is a flowchart showing an illustrative method of operating a power transmitting device 12 with one or more cooling systems 64. As shown in FIG. 8, during the operations of block 302, PTX 12 may gather information. PTX 12 may gather the information using one or more sensors, using communication circuitry, etc. The information gathered by PTX 12 may include information that is indicative of the ambient noise level for PTX 12, may include information that is indicative of the contextual situation for PTX 12, etc.

As specific examples, one or more microphones in input-output devices 28 may be used to measure ambient noise in the environment of PTX 12. One or more position and/or motion sensors such as a GPS sensor in input-output devices 28 may be used to obtain location and/or movement information for PTX 12. PTX 12 may also determine the current time of day, may determine whether the PTX 12 has a wired connection to a power source such as mains power, etc.

Next, during the operations of block 304, PTX 12 may determine cooling capabilities characteristics based on the gathered information from the operations of block 302. PTX 12 may have a predetermined number of configurations for one or more cooling system(s) 64. Each configuration may have a baseline for noise level information and power reservation information. However, the noise level information and power reservation information may optionally be updated in real time based on the gathered information from block 302.

As a specific example, PTX 12 may directly determine that the ambient noise level is high using ambient noise information from one or more microphones. PTX 12 may determine that, based on the real time ambient noise level, cooling system(s) 64 will not generate detectable noise in any of the possible cooling configurations. PTX 12 may therefore change the noise level associated with each cooling profile to ‘none’ or ‘0.’

As another specific example, PTX 12 may infer that the ambient noise level is high based on location and/or movement information indicating that the PTX is moving at a fast speed (e.g., greater than 55 miles per hour). PTX 12 may infer that, based on the speed of the device, the device is likely in a car or other vehicle and therefore the ambient noise level is likely high. PTX 12 may determine that, based on the inferred ambient noise level, cooling system(s) 64 will not generate detectable noise in any of the possible cooling configurations. PTX 12 may therefore change the noise level associated with each cooling profile to ‘none’ or ‘0.’

As another specific example, PTX 12 may infer that the ambient noise level is low based on time of day information indicating that the user is likely sleeping in a quiet environment (e.g., the time of day is 3:00 A.M.). PTX 12 may determine that, based on the inferred ambient noise level, cooling system(s) 64 will generate highly detectable noise in any of the possible cooling configurations. PTX 12 may therefore change the noise level associated with each cooling profile to ‘high.’

As another specific example, PTX 12 may determine that, without a wired connection to mains power, multiple cooling profiles will require a non-zero power reservation. However, when there is a wired connection between PTX 12 and mains power, PTX 12 may determine that no power reservation is required in any of the possible cooling configurations. PTX 12 may therefore change the power reservation level associated with each cooling profile to ‘none’ or ‘0’ when there is a wired connection between PTX 12 and mains power.

After determining the cooling capabilities characteristics based on the gathered information during the operations of block 304, PTX 12 may, during the operations of block 306, transmit a cooling capabilities packet with the cooling capabilities characteristics to PRX 24. As shown and discussed in connection with FIGS. 5 and 6, the cooling capabilities packet 102 may include bits identifying the number of entries/profiles that are available. The cooling capabilities packet 102 may also include, for each cooling profile, one or more bits identifying the profile, one or more bits identifying the cooling level for profile, one or more bits identifying the noise level for profile, and/or one or more bits identifying the power reservation for the profile.

After transmitting the cooling capabilities packet during the operations of block 306, PTX 12 may, during the operations of block 308, receive a cooling profile request packet that identifies a cooling profile from the PRX 24. The cooling profile request packet may be a dedicated packet that identifies a corresponding profile of the plurality of profiles included in the cooling capabilities packet from block 306. Alternatively, the requested profile of the plurality of profiles may be incorporated into a packet with other information such as a received power (RP) packet that also includes information identifying a received power level at PRX 24, a control error (CE) packet that also includes feedback about a desired power level for PRX 24, a configuration (CFG) packet that also provides configuration data from PRX 24 to PTX 12, etc. PTX 12 may, during the operations of block 308, transmit a cooling profile request response packet 108 to PRX 24.

The cooling capabilities packet may be transmitted at block 306 using in-band communication (e.g., using FSK modulation). The cooling capabilities packet may be transmitted at block 306 while simultaneously transmitting wireless power to PRX 24. The cooling profile request packet may be received at block 308 using in-band communication (e.g., using ASK demodulation). The cooling capabilities packet may be received at block 308 while simultaneously transmitting wireless power to PRX 24. This example is merely illustrative and in general, the cooling capabilities packet and the cooling profile request packet may be transmitted using in-band communication or out-of-band communication.

During the operations of block 310, PTX 12 may operate cooling system(s) 64 according to the identified cooling profile from the cooling profile request packet.

The operations of FIG. 8 may be repeated at any desired frequency. As an example, the operations of block 302 may be performed in an ongoing manner by PTX 12. PTX 12 may determine the cooling capabilities characteristics in block 304 at regular intervals, in response to a request from PRX 24, and/or when there is a change to the gathered information from block 302. PTX 12 may transmit the cooling capabilities packet in block 306 at regular intervals, in response to receiving request packet 106 from PRX 24, when there is a change in the characteristics from block 304, and/or when there is a change to the gathered information from block 302.

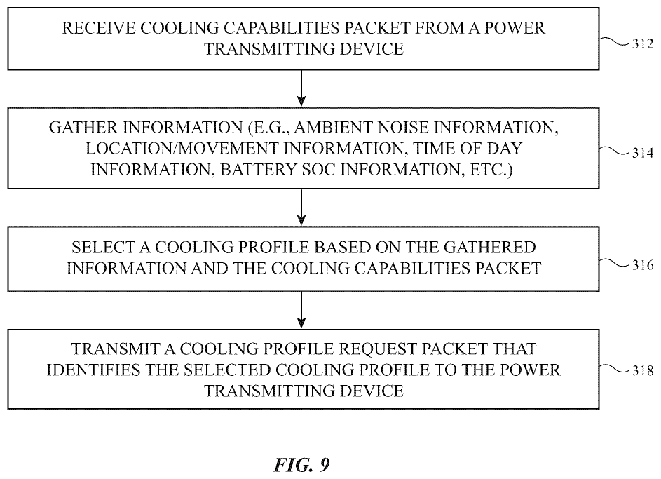

FIG. 9 is a flowchart showing an illustrative method of operating a power receiving device 24. As shown in FIG. 9, during the operations of block 312, PRX 24 may receive a cooling capabilities packet from PTX 12. PRX 24 may optionally transmit a cooling capabilities request packet 106 to PTX 12 during the operations of block 312 (e.g., before receiving the cooling capabilities packet from PTX 12). The cooling capabilities packet 102 may include bits identifying the number of entries/profiles that are available. The cooling capabilities packet 102 may also include, for each cooling profile, one or more bits identifying the profile, one or more bits identifying the cooling level for profile, one or more bits identifying the noise level for profile, and/or one or more bits identifying the power reservation for the profile.

During the operations of block 314, PRX 24 may gather information. PRX 24 may gather the information using one or more sensors, using communication circuitry, etc. The information gathered by PRX 24 may include information that is indicative of the ambient noise level for PRX 24, may include information that is indicative of the contextual situation for PRX 24, etc. As examples, one or more microphones in input-output devices 54 may be used to measure ambient noise in the environment of PRX 24. One or more position and/or motion sensors such as a GPS sensor in input-output devices 54 may be used to obtain location and/or movement information for PRX 24. PRX 24 may also determine the current time of day, may determine a state of charge of battery 34, may determine temperature information using temperature sensor(s) 62, etc.

During the operations of block 314, one or more sensors may be turned on (or have a sampling frequency increased) in response to receiving the packet during the operations of block 312. In other words, control circuitry 38 may increase a power consumption of one or more sensors during the operations of block 314.

During the operations of block 316, PRX 24 may select a cooling profile based on the gathered information from block 314 and the cooling capabilities packet from 312. PRX 24 may select one of the possible cooling profiles identified in cooling capabilities packet 102 received during the operations of block 312. PRX 24 may select one of the possible cooling profiles based on the gathered information from block 314.

As a specific example, PRX 24 may directly determine that the ambient noise level is high using ambient noise information from one or more microphones. PRX 24 may determine that, based on the real time ambient noise level, cooling system(s) 64 in PTX 12 will not generate detectable noise in any of the possible cooling configurations. PRX 24 may therefore be more likely to select a cooling profile with a high noise level during the operations of block 316 than if the ambient noise level were low.

As another specific example, PRX 24 may infer that the ambient noise level is high based on location and/or movement information indicating that the PRX is moving at a fast speed (e.g., greater than 55 miles per hour). PRX 24 may infer that, based on the speed of the device, the device is likely in a car or other vehicle and therefore the ambient noise level is likely high. PRX 24 may determine that, based on the inferred ambient noise level, cooling system(s) 64 in PTX 12 will not generate detectable noise in any of the possible cooling configurations. PRX 24 may therefore be more likely to select a cooling profile with a high noise level during the operations of block 316 than if the ambient noise level were low.

As another specific example, PRX 24 may infer that the ambient noise level is low based on time of day information indicating that the user is likely sleeping in a quiet environment (e.g., the time of day is 3:00 A.M.). PRX 24 may determine that, based on the inferred ambient noise level, cooling system(s) 64 will generate highly detectable noise in any of the possible cooling configurations. PRX 24 may therefore be more likely to select a cooling profile with a low noise level during the operations of block 316 than if the ambient noise level were low.

As another specific example, PRX 24 may infer that the ambient noise level is low based on a contextual determination. For example, a user's calendar may indicate that the user is currently giving a presentation in a work meeting and PRX 24 may infer that the ambient noise level is therefore low. PRX 24 may determine that, based on the inferred ambient noise level, cooling system(s) 64 will generate highly detectable noise in any of the possible cooling configurations. PRX 24 may therefore be more likely to select a cooling profile with a low noise level during the operations of block 316 than if the ambient noise level were low.

As another specific example, PRX 24 may infer, based on time of day information, that the PRX will likely remain coupled to the PTX 12 for a relatively long time (e.g., throughout the night until a normal wake up time for the user). When PRX 24 determines, based on the time of day information, that the PRX will likely remain coupled to the PTX 12 for a relatively long time, PRX 24 may be more likely to select a cooling profile with a high power reservation level during the operations of block 316 (than if the PRX was not likely to remain coupled to the PTX 12 for a relatively long time).

As another specific example, PRX 24 may select a cooling profile based on the state of charge (SOC) of battery 34. When the state of charge of battery 34 is high (e.g., greater than 90%), PRX 24 may be more likely to select a cooling profile with a high power reservation level than if the SOC of battery 34 was low.

As another specific example, PRX 24 may use temperature sensor(s) 62 to determine one or more temperatures associated with PRX 24. If one or more of the temperatures is at, close to, or exceeding a temperature threshold (indicating the device is hotter than desired or close to being hotter than desired for battery charging), PRX 24 may prioritize cooling level when selecting a cooling profile during the operations of block 316. If the temperatures are within a target range, PRX 24 may prioritize noise level and power reservation level over cooling level when selecting a cooling profile during the operations of block 316, as excess cooling may degrade battery charging performance.

After selecting the cooling profile during the operations of block 316, PRX 24 may, during the operations of block 318, transmit a cooling profile request packet that identifies the selected cooling profile to PTX 12. The cooling profile request packet may be a dedicated packet that identifies a corresponding profile of the plurality of profiles included in the cooling capabilities packet from block 312. Alternatively, PRX 24 may incorporate the requested profile into a packet with other information such as a received power (RP) packet that also includes information identifying a received power level at PRX 24, a control error (CE) packet that also includes feedback about a desired power level for PRX 24, a configuration (CFG) packet that also provides configuration data from PRX 24 to PTX 12, etc. After transmitting the cooling profile request packet 104, PRX 24 may receive a cooling profile request response packet 108 during the operations of block 318.

The cooling capabilities request packet may be transmitted at block 312 using in-band communication (e.g., using ASK modulation). The cooling capabilities request packet may be transmitted at block 312 while simultaneously receiving wireless power from PTX 12. The cooling capabilities packet may be received at block 312 using in-band communication (e.g., using FSK demodulation). The cooling capabilities packet may be received at block 312 while simultaneously receiving wireless power from PTX 12. The cooling profile request packet may be transmitted at block 318 using in-band communication (e.g., using ASK modulation). The cooling profile request packet may be transmitted at block 318 while simultaneously receiving wireless power from PTX 12. The cooling profile request response packet may be received at block 318 using in-band communication (e.g., using FSK demodulation). The cooling profile request response packet may be received at block 318 while simultaneously receiving wireless power from PTX 12. This example is merely illustrative and in general, the cooling capabilities request packet, the cooling capabilities packet, the cooling profile request packet, and the cooling profile request response packet may be transmitted using in-band communication or out-of-band communication.

The operations of FIG. 9 may be repeated at any desired frequency. As an example, the operations of blocks 312, 314, and 316 may be performed each time a cooling capabilities packet is received. In another possible example, PRX 24 may monitor the gathered information from block 314 in an ongoing manner. If the gathered information changes (e.g., the ambient noise level changes), PRX 24 may repeat the operations of blocks 316 and 318. In other words, PRX 24 may change the selected cooling profile without receiving a new cooling capabilities packet from PTX 12 if desired. PRX 24 may also optionally transmit a request to PTX 12 for an updated cooling capabilities packet at any time.

The foregoing is merely illustrative and various modifications can be made to the described embodiments. The foregoing embodiments may be implemented individually or in any combination.

What is claimed is:

1. An electronic device comprising:
a wireless power transfer coil;
a rectifier operably coupled to the wireless power transfer coil; and
control circuitry operably coupled to the wireless power transfer coil and rectifier and configured to:
receive a first packet from an additional electronic device using the wireless power transfer coil, wherein the first packet identifies cooling level information and noise level information for a plurality of cooling profiles; and
transmit a second packet to the additional electronic device using the wireless power transfer coil, wherein the second packet identifies a requested cooling profile of the plurality of cooling profiles.

2. The electronic device of claim 1, wherein the first packet identifies power reservation information for the plurality of cooling profiles, wherein the additional electronic device is designed to transmit a maximum wattage of wireless power, and wherein the power reservation information indicates a reduction in the maximum wattage.

3. The electronic device of claim 1, wherein receiving the first packet from the additional electronic device using the wireless power transfer coil comprises receiving the first packet from the additional electronic device using the wireless power transfer coil and while receiving wireless power from the additional electronic device.

4. The electronic device of claim 3, wherein receiving the first packet from the additional electronic device using the wireless power transfer coil comprises receiving the first packet from the additional electronic device using frequency shift keying (FSK) demodulation.

5. The electronic device of claim 1, wherein transmitting the second packet to the additional electronic device using the wireless power transfer coil comprises transmitting the second packet to the additional electronic device using the wireless power transfer coil and while receiving wireless power from the additional electronic device.

6. The electronic device of claim 5, wherein transmitting the second packet to the additional electronic device using the wireless power transfer coil comprises transmitting the second packet to the additional electronic device using amplitude shift keying (ASK) modulation.

7. The electronic device of claim 1, further comprising:
one or more microphones, wherein the control circuitry is configured to:
before transmitting the second packet to the additional electronic device, select the requested cooling profile based at least on sensor data from the one or more microphones.

8. The electronic device of claim 1, further comprising:
one or more temperature sensors, wherein the control circuitry is configured to:
before transmitting the second packet to the additional electronic device, select the requested cooling profile based at least on sensor data from the one or more temperature sensors.

9. The electronic device of claim 1, further comprising:
a battery having a state of charge, wherein the control circuitry is configured to:
before transmitting the second packet to the additional electronic device, select the requested cooling profile based at least on the state of charge of the battery.

10. The electronic device of claim 1, wherein the control circuitry is configured to:
before transmitting the second packet to the additional electronic device, select the requested cooling profile based at least on time of day information.

11. The electronic device of claim 1, wherein the control circuitry is configured to:
increase a power consumption of one or more sensors in response to receiving the first packet from the additional electronic device; and
select the requested cooling profile based on sensor data from the one or more sensors.

12. An electronic device comprising:
a wireless power transfer coil;
an inverter that is configured to supply alternating-current drive signals to the wireless power transfer coil;
one or more cooling systems; and
control circuitry operably coupled to the wireless power transfer coil, the inverter, and the one or more cooling systems and configured to:
transmit a first packet to an additional electronic device using the wireless power transfer coil, wherein the first packet identifies cooling level information and noise level information for a plurality of cooling profiles;
receive a second packet from the additional electronic device using the wireless power transfer coil, wherein the second packet identifies a requested cooling profile of the plurality of cooling profiles; and
operate the one or more cooling systems according to the requested cooling profile.

13. The electronic device of claim 12, wherein the first packet identifies power reservation information for the plurality of cooling profiles, wherein the electronic device is designed to transmit a maximum wattage of wireless power, and wherein the power reservation information indicates a reduction in the maximum wattage.

14. The electronic device of claim 12, wherein transmitting the first packet to the additional electronic device using the wireless power transfer coil comprises transmitting the first packet to the additional electronic device using the wireless power transfer coil and while transmitting wireless power to the additional electronic device.

15. The electronic device of claim 14, wherein transmitting the first packet to the additional electronic device using the wireless power transfer coil comprises transmitting the first packet to the additional electronic device using frequency shift keying (FSK) modulation.

16. The electronic device of claim 12, wherein receiving the second packet from the additional electronic device using the wireless power transfer coil comprises receiving the second packet from the additional electronic device using the wireless power transfer coil and while transmitting wireless power to the additional electronic device.

17. The electronic device of claim 16, wherein receiving the second packet from the additional electronic device using the wireless power transfer coil comprises receiving the second packet from the additional electronic device using amplitude shift keying (ASK) demodulation.

18. The electronic device of claim 12, wherein the one or more cooling systems comprises a fan.

19. The electronic device of claim 12, wherein the one or more cooling systems comprises a thermoelectric heat pump.

20. The electronic device of claim 12, further comprising:
one or more microphones, wherein the control circuitry is configured to:
before transmitting the first packet to the additional electronic device, adjust the noise level information for the plurality of cooling profiles based at least on sensor data from the one or more microphones.
